(19) United States
(12) Patent Application Publication
(10) Pub. No.: US 2021/0273132 A1
(43) Pub. Date: Sep. 2, 2021

(54) OPTOELECTRONIC DEVICE HAVING A DIODE MATRIX

(71) Applicant: Aledia, Echirolles (FR)

(72) Inventors: Tiphaine Dupont, Grenoble (FR); Ivan-Christophe Robin, Grenoble (FR)

(73) Assignee: Aledia, Echirolles (FR)

(21) Appl. No.: 17/253,223

(22) PCT Filed: Jun. 19, 2019
(86) PCT No.: PCT/FR2019/051507

§ 371 Date: Dec. 17, 2020

(30) Foreign Application Priority Data
Jun. 20, 2018 (FR) 1855450

(51) Int. Cl. H01L 33/08; H01L 33/10; H01L 33/18; H01L 33/24; H01L 33/00

(52) U.S. Cl. CPC H01L 33/08; H01L 33/105; H01L 2933/0083; H01L 33/24; H01L 33/0093; H01L 33/18

(57) ABSTRACT

An optoelectronic device including an array of axial diodes, each diode forming a resonant cavity having a standing electromagnetic wave forming therein, each light-emitting diode including an active area located substantially at the level of an extremum of the electromagnetic wave, the array forming a photonic crystal configured to maximize the intensity of the electromagnetic radiation supplied by the diode array.

The present patent application claims the priority benefit of French patent application FR18/55450 which is herein incorporated by reference.

### BACKGROUND

The present disclosure concerns an optoelectronic device, particularly a display screen or an image projection device, comprising light-emitting diodes made up of semiconductor materials, and their manufacturing methods.

### DISCUSSION OF THE RELATED ART

It is known to project images on inputs of waveguide gratings of transparent screens, for example, eyeglasses, car windshields or glass panes, the images being then projected towards the user's eye. Such is for example the case for smart glasses or augmented reality glasses. To achieve this, optoelectronic devices project images on the screen. The images are then guided in the screen to reach a system enabling the images to be seen by a user. The optoelectronic devices may comprise light-emitting diodes, for example, made up of semiconductor materials. Displays are generally configured to properly guide only the radiation emitted by the light-emitting diodes which substantially propagates in a given direction. The directivity of the radiation supplied by the light-emitting diodes thus is a significant characteristic of such optoelectronic devices.

### SUMMARY

Thus, an embodiment provides an optoelectronic comprising an array of axial diodes, each diode forming a resonant cavity having a standing electromagnetic wave forming therein, each light-emitting diode comprising an active area located substantially at the level of an extremum of the electromagnetic wave, the array forming a photonic crystal configured to maximize the intensity of the electromagnetic radiation supplied by the diode array.

According to an embodiment, the array comprises a support having the diodes resting thereon, each diode comprising a stack of a first semiconductor region resting on the support, of the active area in contact with the first semiconductor region, and of a second semiconductor region in contact with the active area.

According to an embodiment, the device comprises a reflective layer between the support and the first regions of the diodes.

According to an embodiment, the reflective layer is made of metal.

According to an embodiment, the second regions of the diodes are covered with a conductive layer at least partly transparent to the radiations emitted by the diodes.

According to an embodiment, the height of at least one of the diodes is substantially proportional to kλ/2n, where λ is the wavelength of the radiation emitted by the diode, k is a positive integer, and n is substantially equal to the effective refraction index of the diode in the considered optical mode.

According to an embodiment, the diodes are separated by an electrically-insulating material.

According to an embodiment, the array comprises at least first and second diode assemblies, the diodes of the first assembly having a same first height, the diodes of the second assembly having a same second height, the first and second heights being different.

According to an embodiment, for at least one of the diodes, the first region of the diode comprises at least two portions separated by an etch stop layer.

According to an embodiment, each etch stop layer has a thickness in the range from 1 to 200 nm.

According to an embodiment, the quotient of the pitch of the array to the wavelength of the supplied electromagnetic radiation is in the range from approximately 0.4 to approximately 0.92.

According to an embodiment, the diodes are light-emitting diodes or photodiodes.

Another embodiment provides a method of manufacturing an optoelectronic comprising an array of axial diodes, each diode forming a resonant cavity having a standing electromagnetic wave forming therein, the active area of each diode being located substantially at the level of an extremum of the electromagnetic wave, the pitch of the array being configured to maximize the intensity supplied by the diode array.

According to an embodiment, the forming of the diodes of the array comprises:
forming first regions on a substrate, the first regions being separated from one another by the pitch of the array;
forming an active area on each first region; and
forming a second region on each active area.

According to an embodiment, the method comprises a first step of etching all the second regions so that they have a same height.

According to an embodiment, the method comprises a second step of etching all the first regions so that they have the height enabling the active area to be located at the level of an extremum of the electromagnetic wave.

According to an embodiment, the second etch step is carried out before the forming of the active areas.

According to an embodiment, the second etch step is preceded by a step of removing the substrate, the second etch step being carried out from the end of the diode which was closest to the substrate.

According to an embodiment, the method comprises forming at least one layer in the first region of at least one of the diodes capable of being used as a stop layer for the second etch step.

According to an embodiment, the diodes are light-emitting diodes or photodiodes.

### BRIEF DESCRIPTION OF THE DRAWINGS

The foregoing and other features and advantages will be discussed in detail in the following non-limiting description of specific embodiments in connection with the accompanying drawings, among which:

FIG. 1 is a partial simplified perspective view of an embodiment of an axial light-emitting diode;

FIG. 2 is a partial simplified perspective view of an embodiment of an array of light-emitting diodes;

FIGS. 3A and 3B schematically show examples of layouts of the light-emitting diodes of the array of FIG. 2;

FIGS. 4A to 4F are partial simplified cross-section views illustrating the structures obtained at steps of another embodiment of a method of manufacturing the array of FIG. 2;

FIGS. 5A to 5D are partial simplified cross-section views illustrating the structures obtained at other steps of an embodiment of a method of manufacturing the array of FIG. 2;

FIG. 6 is a partial simplified cross-section view illustrating the structure obtained at a step of an embodiment of a method of manufacturing the array of FIG. 2;

FIGS. 7A and 7B are partial simplified cross-section views illustrating the structures obtained at steps of another embodiment of a method of manufacturing the array of FIG. 2;

FIG. 8 is a graph showing the intensity emitted by an array such as that in FIG. 2 according to certain characteristics of the array;

FIGS. 9A to 9E are graphs illustrating simulation results for embodiments of light-emitting diodes arrays; and

FIGS. 10A to 10E are graphs illustrating simulation results for other embodiments of light-emitting diode arrays.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. In particular, the considered optoelectronic devices optionally comprise other components which will not be detailed.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the concerned elements in the drawings. The terms “approximately”, “about”, “substantially”, and “in the order of” are used herein to designate a tolerance of plus or minus 10%, preferably of plus or minus 5%, of the value in question.

When speaking of “transparent” or “reflective” elements, elements transparent or reflective for the wavelengths at which the device is intended to operate, for example, the wavelengths of the electromagnetic radiations emitted by the considered light-emitting diodes, are considered.

Further, the term “active area” of a light-emitting diode designates the region of the light-emitting diode from which most of the electromagnetic radiation provided by the light-emitting diode is emitted.

The term axial light-emitting diode designates a three-dimensional structure having an elongated shape, for example, cylindrical, along a main direction having at least two dimensions, called minor dimensions, in the range from 5 nm to 2.5 μm, preferably from 50 nm to 2.5 μm. The third dimension, called major dimension, is greater than or equal to 1 time, preferably greater than or equal to 5 times, and more preferably greater than or equal to 10 times the largest minor dimension. In certain embodiments, the minor dimensions may be smaller than or equal to approximately 1 μm, preferably in the range from 100 nm to 1 μm, more preferably from 100 nm to 800 nm. In certain embodiments, the height of each light-emitting diode may be greater than or equal to 500 nm, preferably in the range from 1 μm to 50 μm.

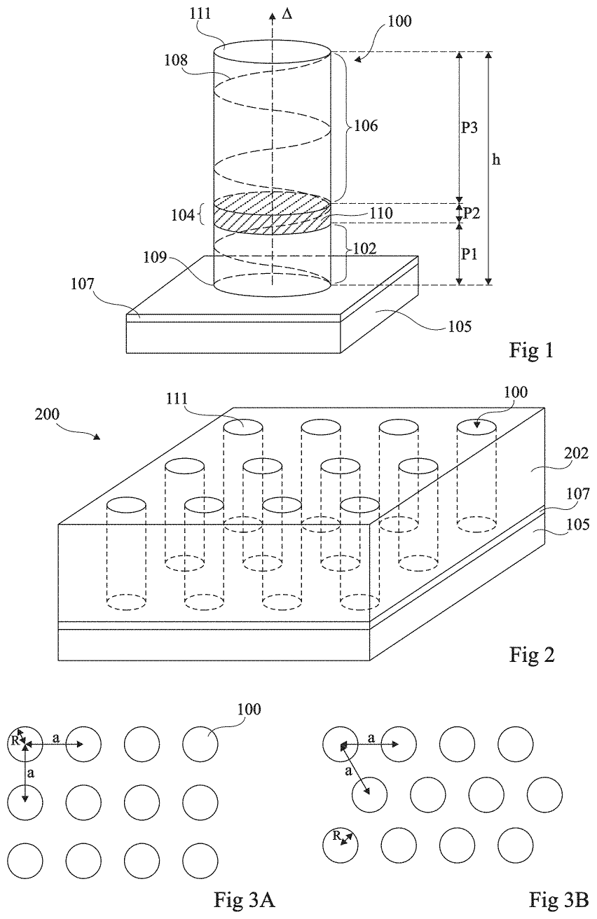

FIG. 1 is a perspective view of an embodiment of an axial light-emitting diode 100.

Light-emitting diode 100 comprises a stack of a region 102, of an active area 104, and of a region 106. The upper surface of region 102 is in contact with the lower surface of active area 104. The upper surface of active area 104 is in contact with the lower surface of region 106.

Light-emitting diode 100 is called axial since active area 104 is in line with region 102 and region 106 is in line with active area 104. An axis A corresponds to the axis of the axial light-emitting diode.

Region 102 is made of a doped semiconductor material of a first conductivity type, for example, P doped. Region 102 rests on a support 105, for example, an electronic circuit, for example, an interposer, comprising interconnections contacting region 102 and enabling to control light-emitting diode 100. Axis A is then orthogonal to the upper surface of support 105. Lower surface 109 of region 102, that is, the surface on the side of support 105, is in contact with a reflective layer. For example, lower surface 109 may be separated from support 105 by a layer 107 made of metal, for example, aluminum. For example, metal layer 107 may totally or partly cover support 105.

Region 106 is made of a semiconductor material of a second conductivity type, for example, type N, different from the first conductivity type. Upper surface 111 of region 106 is for example covered with a layer (or with a stack of layers) of one or a plurality of transparent or semi-reflective materials, not shown, for example, a layer of transparent conductive oxide (TCO).

Regions 102 and 106 may be at least partly made up of semiconductor materials mainly comprising a III-V compound, for example, a III-N compound. Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus (P) or arsenic (As). Generally, the elements in the III-V compound may be combined with different molar fractions.

Regions 102 and 106 may be at least partly made up of semiconductor materials mainly comprising a II-VI compound. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (0) and tellurium (Te). Examples of II-VI compounds are ZnO, ZnMgO, CdZnO, CdZnMg0, CdHgTe, CdTe, or HgTe. Generally, the elements in the II-VI compound may be combined with different molar fractions.

Regions 102 and 106 may be at least partly made up of semiconductor materials mainly comprising at least one group-IV compound. Examples of group-IV semiconductor materials are silicon (Si), carbon (C), germanium (Ge), silicon carbide alloys (SiC), silicon-germanium alloys (SiGe), or germanium carbide alloys (GeC).

Regions 102 and 106 may comprise a dopant. As an example, for III-V compounds, the dopant may be selected from the group comprising a P-type group-II dopant, for example, magnesium (Mg), zinc (Zn), cadmium (Cd), or mercury (Hg), a P-type group-IV dopant, for example, carbon (C), or an N-type group-IV dopant, for example, silicon (Si), germanium (Ge), selenium (Se), sulfur (S), terbium (Tb), or tin (Sn).

Preferably, region 102 is a P-doped GaN region and region 106 is an N-doped GaN region.

For each light-emitting diode, active area 104 may comprise confinement means. As an example, area 104 may comprise a single quantum well. It then comprises a semiconductor material different from the semiconductor material forming regions 102 and 106 and having a bandgap smaller than that of the material forming regions 102 and 106. Active area 104 may comprise multiple quantum wells. It then comprises a stack of semiconductor layers forming an alternation of quantum wells and of barrier layers.

In FIG. 1, the shown light-emitting diode 100 has the shape of a cylinder with a circular base of axis Δ. However, light-emitting diode 100 may have the shape of a cylinder of axis Δ with a polygonal base, for example, square, rectangular, or hexagonal. Preferably, light-emitting diode 100 has the shape of a cylinder with a hexagonal base.

Height h of light-emitting diode 100, that is, the distance between lower surface 109 of region 102 and upper surface 111 of region 106, is substantially proportional to k*λ/2*neff, λ being the wavelength of the radiation emitted by the light-emitting diode, neff being the effective refraction index of the light-emitting diode in the considered optical mode, and k being a positive integer. The effective refraction index is for example defined in work “Semiconductor Optoelectronic Devices: Introduction to Physics and Simulation” by Joachim Piprek.

Height h is equal to the sum of height P1 of region 102, of height P2 of active area 104, of height P3 of region 106, and of the height of the optional layers which may cover surface 111.

Light-emitting diode 100 forms a resonant cavity along axis Δ. Thus, a standing electromagnetic wave along axis Δ forms in the light-emitting diode in operation, which is very schematically illustrated in FIG. 1 by a curve 108. The wave follows the axes of symmetry of light-emitting diode 100. Thus, the wave for example has a symmetry of revolution if the light-emitting diode has a circular cross-section. A standing electromagnetic wave along axis Δ means an electromagnetic wave having its nodes, that is, the points of zero intensity, fixed in space and having an intensity at the other points which may be time-variable.

According to an embodiment, active area 104 is advantageously located at the level of an extremum 110 of the electromagnetic wave. The power intensity of the radiation emitted by the light-emitting diode is then more significant and the radiation which escapes from the light-emitting diode is more intense than in the case of a light-emitting diode of same structure having an active area which would not be located at an extremum of the electromagnetic wave.

FIG. 2 is a perspective view of an embodiment of an array 200 of light-emitting diodes 100.

Array 200 comprises light-emitting diodes 100 located in a layer 202 of a filling material, for example, an electrically-insulating material, for example, silicon oxide. In the embodiment of FIG. 2, all the light-emitting diodes 100 have the same height. The thickness of layer 202 is for example selected to be equal to the height of the light-emitting diodes so that the upper surface of layer 202 is coplanar with the upper surface of each light-emitting diode, that is, with the upper surface 111 of each region 106.

An electrode layer, not shown, is in contact with the upper surfaces of the light-emitting diodes. It may be a conductive layer covering layer 202. The electrode layer may be a transparent or semi-reflective layer.

The upper surface of the array corresponds to the surface of the electrode layer opposite to the light-emitting diodes.

Twelve light-emitting diodes 100 are shown in FIG. 2. In practice, array 200 may for example comprise from 7 to 100,000 light-emitting diodes.

The light-emitting diodes 100 of array 200 are arranged in rows and in columns (3 rows and 4 columns being shown as an example in FIG. 2). The pitch of the array is the distance between the axis of a light-emitting diode 100 and the axis of a close light-emitting diode 100, in the same row or in an adjacent row. Pitch a is substantially constant. More particularly, the pitch of the array is selected so that array 200 forms a photonic crystal. The formed photonic crystal is for example, a 2D photonic crystal.

The properties of the photonic crystal formed by array 200 are advantageously selected so that the intensity of the radiation emitted by all the light-emitting diodes 100 of the array is more significant and so that the radiation is more directional than in the case of an assembly of light-emitting diodes 100 which would not form a photonic crystal.

In the example of FIG. 2, index neff is substantially equal to the average of the refraction indexes of GaN of light-emitting diodes 100 and of the material of layer 202, weighted by surface area ratio FF between the two materials. Index neff is thus for example substantially equal to: FF*nGaN+(1−FF)*nSiO2, where nGaN is the refraction index of the GaN of light-emitting diodes 100, nSiO2 is the refraction index of the material of layer 202, and FF is equal to the quotient of the area of the horizontal cross-section of a light-emitting diode 100 to the area of the horizontal cross-section of a periodic element of array 200. For example, a periodic element of array 200 has a square horizontal cross-section, centered on a light-emitting diode 100 and a side length equal to the distance between the axes Δ of two neighboring light-emitting diodes.

FIGS. 3A to 3B schematically show examples of layouts of the light-emitting diodes 100 of array 200. In particular, FIG. 3A illustrates a so-called square mesh layout and FIG. 3B illustrates a so-called hexagonal mesh layout.

FIGS. 3A and 3B further illustrate pitch a of the array, that is, the distance between the axis of a light-emitting diode and the axis of the closest light-emitting diode in the same row or in an adjacent row. FIGS. 3A and 3B also illustrate the radius R of a light-emitting diode 100 having a circular base. In the case where the light-emitting diode does not have a circular base, radius R corresponds to the radius of the circle having the base inscribed therein.

FIG. 3A shows three rows of four light-emitting diodes 100. In such a layout, a light-emitting diode 100 is located at each intersection of a row and of a column, the rows being perpendicular to the columns.

FIG. 3B shows, like FIG. 3A, three rows of four light-emitting diodes 100. In such a layout, the diodes in a row are shifted by half pitch a with respect to the light-emitting diodes in the previous row and the next row.

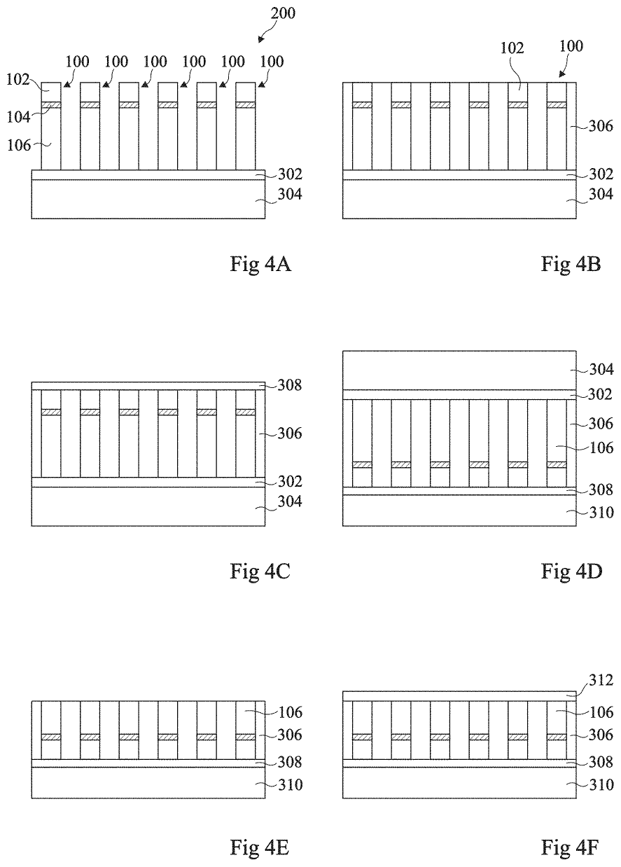

FIGS. 4A to 4F are cross-section views illustrating the structures obtained at steps of an embodiment of a method of manufacturing array 200 of FIG. 2.

FIG. 4A illustrates the structure obtained after the forming steps described hereafter.

A seed layer 302 is formed on a substrate 304. Light-emitting diodes 100 are then formed from seed layer 302. More particularly, light-emitting diodes 100 are formed in such a way that regions 106 are in contact with seed layer 302. The active area 104 of each light-emitting diode 100 is located on region 106 and region 102 is located on active area 104.

Further, light-emitting diodes 100 are located to form array 200, that is, to form rows and columns with the desired pitch of array 200. Only one row is shown in FIGS. 4A to 4F.

A mask, not shown, may be formed before the forming of the light-emitting diodes on seed layer 302 to only expose the portions of seed layer 302 at the locations where the light-emitting diodes will be located. As a variation, the seed layer may be etched to form pads located at the locations where the light-emitting diodes will be located.

The method of growth of light-emitting diodes 100 may be a method such as chemical vapor deposition (CVD) or metal-organic chemical vapor deposition (MOCVD), also known as metal-organic vapor phase epitaxy (MOVPE). However, methods such as molecular-beam epitaxy (MBE), gas-source MBE (GSMBE), metal-organic MBE (MOMBE), plasma-assisted MBE (PAMBE), atomic layer epitaxy (ALE), or hydride vapor phase epitaxy (HVPE) may be used. However, electrochemical processes may be used, for example, chemical bath deposition (CBD), hydrothermal processes, liquid aerosol pyrolysis,

The conditions of growth of light-emitting diodes 100 are such that all the light-emitting diodes of array 200 substantially form at the same speed. Thus, the heights of regions 102 and 106 and the height of active area 104 are substantially identical for all the light-emitting diodes of array 200.

It is further considered that the heights of region 102 and of active area 104 substantially correspond to previously—described values P1 and P2 determined so that, in operation, active area 104 is located on an extremum of the electromagnetic wave. The height of region 106 is greater than the desired value P3. It may be difficult to accurately control the height of region 106, particularly due to the beginning of the growth of region 106 from seed layer 302. Further, the forming of the semiconductor directly on the seed layer may cause crystal defects in the semiconductor material just above the seed layer. It may thus be desired to remove a portion of region 106.

FIG. 4B illustrates the structure obtained after the forming of a layer 306 of a filling material corresponding to the material of layer 202, for example, an electrically-insulating material, for example, silicon oxide. Layer 306 is for example formed by depositing a layer of filling material on the structure, the layer having a thickness greater than the height of light-emitting diodes 100. The layer of filling material is then partially removed to be planarized in order to expose the upper surfaces of regions 102, each corresponding to the surface 109 described in relation with FIG. 1. The upper surface of layer 306 is thus substantially coplanar with the upper surface of each region 102. As a variation, the method may comprise an etch step during which regions 102 are partially etched.

The filling material is selected so that the photonic crystal formed by array 200 has the desired properties, that is, it improves the directivity and the intensity of the radiation emitted by light-emitting diodes 100.

FIG. 4C illustrates the structure obtained after the deposition of a layer 308 on the structure obtained at the previous step. Layer 308 is a reflective layer, for example, a metal layer, for example, an aluminum layer. Layer 308 is also an electrically-conductive layer connecting all the regions 102 of array 200 to one another. The light-emitting diodes 100 of array 200 an thus be controlled via layer 308.

FIG. 4D illustrates the structure obtained after the bonding to a support 310 of the surface of layer 308 which is not in contact with layer 306, for example, by metal-to-metal bonding, by thermocompression or by soldering with the use of a eutectic on the side of support 310. Support 310 is for example an electronic circuit, for example, an interposer, comprising interconnections, not shown, in contact with layer 308.

FIG. 4E illustrates the structure obtained after the removal of substrate 304 and of seed layer 302. Further, layer 306 and regions 106 are etched in such a way that the height of each region 106 has value P3 enabling the active area to be placed as previously described. This step advantageously enables to exactly control height h of the light-emitting diodes and to remove the portions of regions 106 which may have crystal defects.

FIG. 4F illustrates the structure obtained after the deposition of a layer 312 on the structure obtained at the previous step. Layer 312 is transparent or semi-reflective, to allow the emission of the radiation, and conductive, to control light-emitting diodes 100. Layer 312 is for example made of transparent conductive oxide, for example, of zinc oxide or of indium tin oxide, or may be a stack of oxide layers to be able to adjust the reflectivity of the stack according to the thicknesses and the refractions indexes of the materials of the stack.

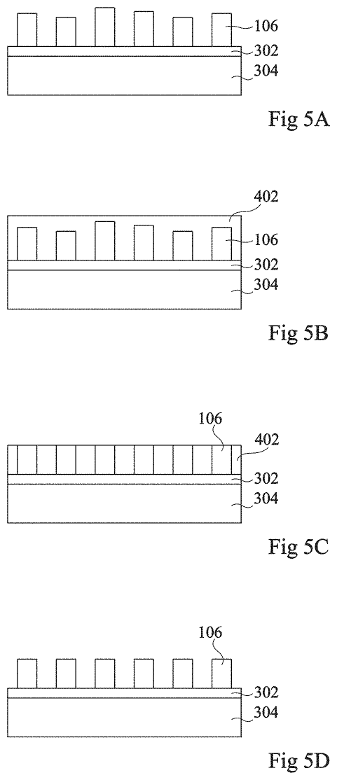

FIGS. 5A to 5D are cross-section views illustrating the structures obtained at other steps of an embodiment of a method of manufacturing the array 200 of FIG. 2. More particularly, FIGS. 5A to 5D at least partially illustrate the forming of regions 106.

FIG. 5A illustrates the structure obtained after the forming of regions 106 on seed layer 302 covering substrate 304.

The present embodiment is for example adapted to the case where the conditions of growth of light-emitting diodes 100 are such that regions 106 having different heights are obtained.

FIG. 5B illustrates the structure after the forming of a layer 402 of filling material, for example, silicon oxide, on regions 106. The forming of layer 402 for example comprises depositing a layer of filling material having a thickness greater than the height of regions 106 located on layer 302.

FIG. 5C illustrates the structure obtained after the etching of regions 106 and of layer 402 so that the upper surfaces of all regions 106 and the upper surface of layer 402 are coplanar. Regions 106 then all have the same height.

FIG. 5D illustrates the structure obtained after the removal of layer 402.

The growth of light-emitting diodes 100 can then be resumed, for example, to reach the structure described in relation with FIG. 4A. Light-emitting diodes 100 then have a growth substantially at the same speed. The step of FIG. 5D is for example followed by a step of growth of the rest of region 106 and of growth of active area 104 and of region 102. As a variation, the step of FIG. 5D may be directly followed by a step of growth of active area 104 and of region 102. In this case, the height of region 106 in FIG. 5D already corresponds to the height of region 106 of FIG. 4A. Regions 106 and 102 and area 104 thus substantially have the same height whatever the light-emitting diode in the array. The method described in relation with FIGS. 4A to 4F can then be resumed.

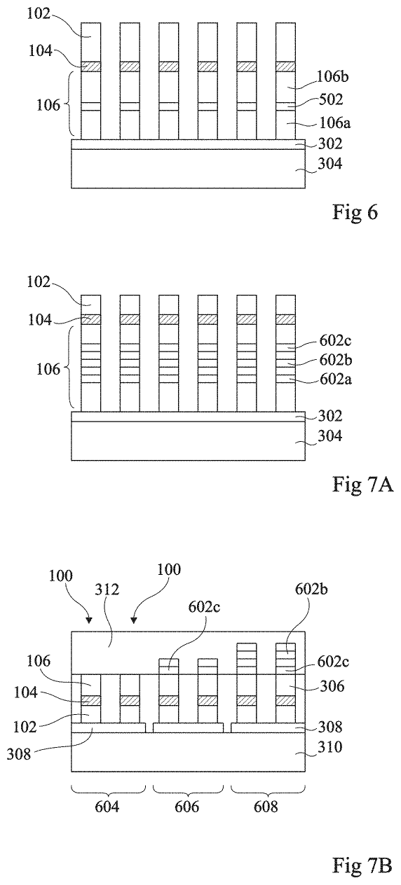

FIG. 6 is a cross-section view illustrating the structure obtained at a step of another embodiment of a method of manufacturing the array of FIG. 2. This step for example follows the step illustrated in FIG. 5D.

During this step, an etch stop layer 502 is formed on the portions 106a of regions 106 previously formed and planarized, for example, during the method described in relation with FIGS. 5A to 5D. As an example, the material forming etch stop layer 502 may be a nitride, a carbide, a metal, or a boride of a transition metal from column IV, V, or VI of the periodic table of elements, or a combination of these compounds. As an example, etch stop layer 502 may be made of aluminum nitride (AlN), of aluminum oxide (Al2O3), of boron (B), of boron nitride (BN), of titanium (Ti), of titanium nitride (TiN), of tantalum (Ta), of tantalum nitride (TaN), of hafnium (Hf), of hafnium nitride (HfN), of niobium (Nb), of niobium nitride (NbN), of zirconium (Zr), of zirconium borate (ZrB2), of zirconium nitride (ZrN), of silicon carbide (SiC), of tantalum carbo-nitride (TaCN), of magnesium nitride in MgxNy form, where x is approximately equal to 3 and y is approximately equal to 2, for example, magnesium nitride in Mg3N2 form. Layer 502 for example has a thickness in the range from approximately 1 to 100 nm.

Portions 106b of regions 106 are then formed on layers 502. Active areas 104 and regions 102 are then formed on regions 106.

The height of portion 106b substantially corresponds to the desired height P3. The height of portion 106a is sufficiently large to include most of the crystal defects.

The step of FIG. 6 may then be followed by the steps described in relation with FIGS. 4B to 4F, the etching of the step previously described with FIG. 4E stopping on etch stop layer 502 and for example comprising the removal of etch stop layer 502.

FIGS. 7A and 7B are cross-section views illustrating the structures obtained at steps of another embodiment of a method of manufacturing the array of FIG. 2. More particularly, FIGS. 7A and 7B illustrate the manufacturing of an array comprising light-emitting diodes having different heights.

FIG. 7A illustrates a step equivalent to the step of FIG. 4A corresponding to the growth of light-emitting diodes 100, with the difference that during this step, a plurality of etch stop layers are formed in each region 106. In FIG. 7A, three etch stop layers 602a, 602b, and 602c have been formed in each region 106, layer 602a being the closest to seed layer 302 and layer 602c being the closest to active area 104. The etch stop layers are for example made of the same material and are separated from one another by portions of regions 106.

FIG. 7B illustrates the array of light-emitting diodes obtained from the structure of FIG. 7A after steps similar to those previously described in relation with FIGS. 4B, 4C, and 4D.

The method then comprises etch steps. During these steps, for an assembly 604 of light-emitting diodes 100, the region 106 of each light-emitting diode 100 is etched from the free end to etch stop layer 602c, which is also etched. For an assembly 606 of light-emitting diodes 100, the region 106 of each light-emitting diode 100 is etched from the free end all the way to etch stop 602b, which is then etched to expose the portion of region 106 located between etch stop layers 602b and 602c. For an assembly 608 of light-emitting diodes 100, the region 106 of each light-emitting diode 100 is etched from the free end all the way to stop layer 602a, which is then etched to expose the portion of region 106 located between etch stop layers 602b and 602a.

The light-emitting diodes of the different assemblies 604, 606, and 608 for example supply a radiation having a same wavelength X and for example have total heights h equal to different multiples of X/2n. As a variation, the light-emitting diodes of different assemblies 604, 606, and 608 may be adapted to emitting radiations of different wavelengths and thus have different heights.

The material and the dimensions of etch stop layer 602a, 602b, and 602c are selected so that they have a negligible impact on the operation of the light-emitting diodes.

Layer 312 is then deposited on the structure. Layer 312 may for example surround an upper portion of region 106 of certain light-emitting diode assemblies. The thickness of layer 312 is selected to cover the upper surface of each light-emitting diode 100.

Reflective layer 308 is for example divided into a plurality of non-connected portions, each portion being in contact with an assembly of light-emitting diodes. Thus, the different light-emitting diode assemblies may be controlled independently from one another.

Generally, the number of etch stop layers corresponds to the number of heights of different light-emitting diodes desired in the array.

An advantage of the previously-described manufacturing method embodiments is that they enable to accurately position active area 104 within light-emitting diode 100, that is, to control the values of heights P1, P2, and P3.

The following drawings 8, 9A to 9E and 10A to 10E illustrate the results of simulations concerning examples of arrays according to the previously-described embodiments. Such simulations illustrate a method of determining the dimensions of the light-emitting diodes and of the pitch of the array. For the simulations, the light-emitting diodes of the considered array comprise GaN regions 102 and 106. Regions 102 have a thickness greater than or equal to 30 nm. Active areas 104 comprise a single InGaN layer, having a thickness equal to 40 nm. Layer 306 is made of silicon oxide and layer 308 of reflective material is made of aluminum. Layer 312 has a 50-nm thickness. Layer 312 is made of transparent conductive oxide having a refraction index substantially equal to 2 at the considered wavelength, for example, ITO. The considered light-emitting diodes 100 have the shape of a cylinder with a circular base. The light-emitting diodes of the array are arranged with a square mesh. Each row and each column comprises seven light-emitting diodes. The array thus here comprises forty-nine light-emitting diodes. It is considered in the following simulations that all light-emitting diodes have the same height.

It is chosen to impose the following constraints regarding the filling rate for a square mesh: 5%≤πR²/a²≤65%, where R is the radius of the cross-section of each light-emitting diode and a is the pitch of the array.

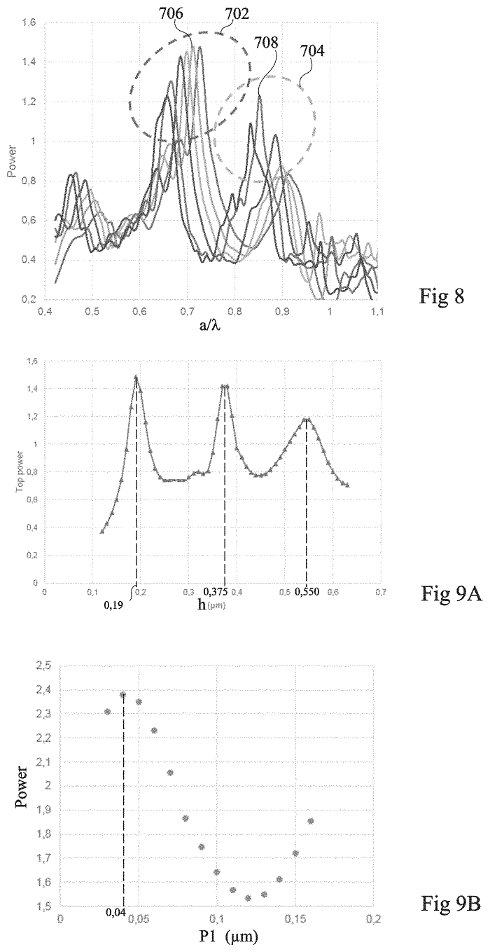

FIG. 8 is a graph comprising curves of the variation of the intensity (Power) of the radiation emitted by the array according to a first quotient a/λ, where λ is the wavelength of the radiation emitted by the array, each example of array, and thus each curve, corresponding to a different value of a second quotient 2πR/λ.

For clarity, only six curves have been shown in FIG. 8. In practice, simulations have been performed by varying the second quotient 2πR/λ from 0.7 to 1.7.

This drawing enables to determine one or a plurality of ranges of values of the first quotient a/λ for which intensity peaks appear. It is possible to observe two areas 702 and 704, each corresponding to such a range of values. Each of the curves comprises a peak in at least one of the two areas 702 and 704.

Area 702 corresponds to a range of values of first quotient a/λ substantially in the range from approximately 0.4 to approximately 0.82. Area 704 corresponds to a range of values of first quotient a/λ substantially in the range from approximately 0.8 to approximately 0.92.

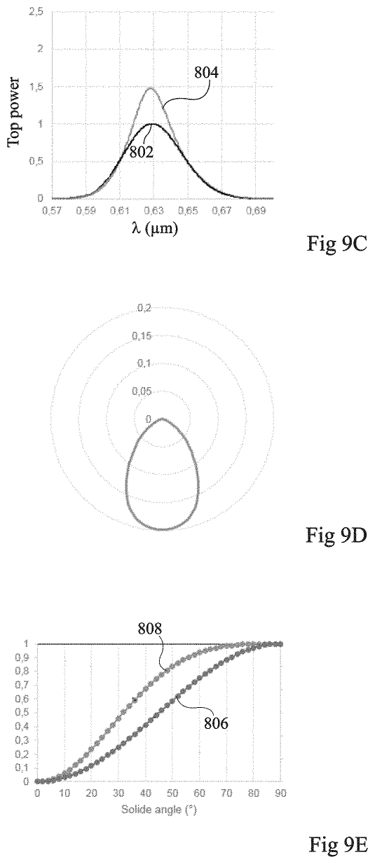

FIGS. 9A to 9E are graphs illustrating results of simulations for an embodiment of an array of light-emitting diodes. More particularly, FIGS. 9A and 9B illustrate simulations in the case of an array having its first quotient a/λ in the range associated with area 702 enabling to determine optimal characteristics for the array and FIGS. 9C to 9E show results of simulations in the case of the selected characteristics.

Wavelength λ of the radiations emitted by the light-emitting diodes is selected, for example, at 450 nm for blue light, at 530 nm for green light, or at 630 nm for red light. The selection of one of the curves having a maximum in the range corresponding to area 702 and the value of the first quotient a/λ at the maximum of the selected curve enables to determine radius R of the light-emitting diodes and pitch a of the array.

As an example, a 630-nm wavelength and the curve 706 having its extremum, in area 702, corresponding to the most significant emitted intensity among all the curves, are here selected. First quotient a/λ is then substantially equal to 0.7111 and second quotient 2πR/λ is thus substantially equal to 1.1. Thus, pitch a is substantially equal to 448 nm and radius R is substantially equal to 110 nm.

FIG. 9A illustrates the intensity emitted by the upper surfaces of the light-emitting diodes of the array (Top Power) according to the total height h of the light-emitting diodes in the previously-selected conditions.

It is possible to observe three intensity peaks for heights h equal to 190 nm, 375 nm, and 550 nm.

A value of h is selected among these values. Although the intensity emitted by the upper surfaces is greater for height h equal to 190 nm, height h is here selected to be equal to 375 nm for the ease of manufacturing.

FIG. 9B illustrates the intensity emitted by the array of light-emitting diodes having the previously-determined characteristics according to thickness P1 of regions 102. It is possible to observe, over the given range of values, a single maximum, which enables to determine the value, here, 40 nm, for thickness P1 of regions 102.

FIG. 9C illustrates the intensity of the radiation emitted by the upper surface of the array according to wavelength λ of the radiations emitted by the light-emitting diodes. Curve 802 corresponds to an array of light-emitting diodes which do not form a photonic crystal and curve 804 corresponds to an array forming a photonic crystal and having the previously-determined characteristics. The values have been normalized so that the maximum of curve 802 corresponds to value 1.

It can be observed that the array of light-emitting diodes according to an embodiment and having the previously-determined characteristics emits a radiation having an intensity, at the level of its upper surface, which is 1.5 times greater than the intensity of a radiation emitted by an array which does not form a photonic crystal.

FIG. 9D illustrates the intensity of the radiation emitted by the previously-described array according to the angle between the emitted radiation and the direction orthogonal to the upper surface of the array. The radiation emitted by the array is advantageously directional.

FIG. 9E illustrates the intensity of the radiation emitted by an array in cumulated fashion according to a solid angle measured with respect to the upper surface of the array. FIG. 9E comprises a curve 806 corresponding to an array of axial light-emitting diodes which do not form resonant cavities and a curve 808 corresponding to a photonic crystal formed of axial light-emitting diodes forming resonant cavities and having the previously-determined characteristics.

It can be observed that the array according to an embodiment (curve 808) supplies a more directional intensity. Indeed, the array corresponding to curve 808 supplies 50% of its intensity at a 30° solid angle while the array corresponding to curve 806 supplies 50% of its intensity at a 45° solid angle.

Thus, an array according the embodiment of FIG. 2 and having the previously-determined characteristics supplies a radiation of greater intensity and more directional than the radiation supplied by an array of light-emitting diodes corresponding to curve 806.

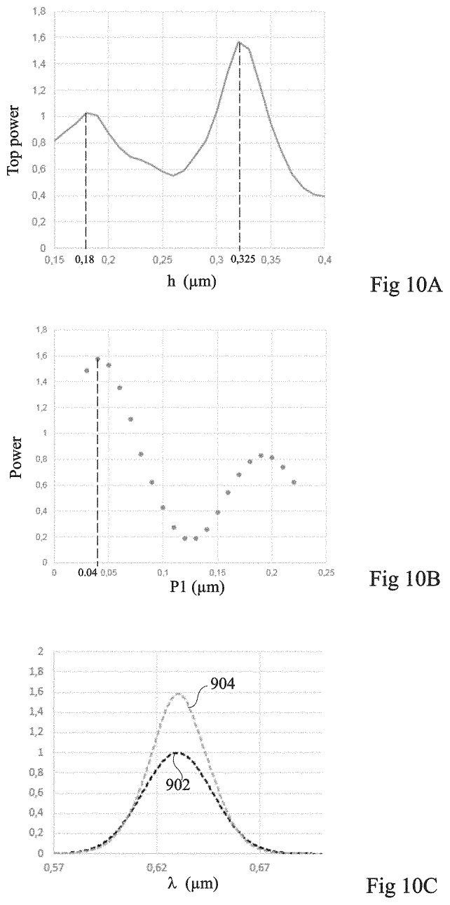

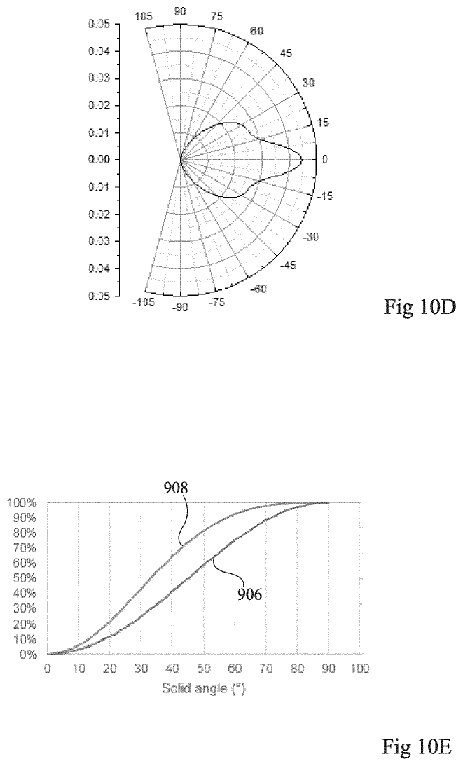

FIGS. 10A to 10E are graphs illustrating results of simulations for another embodiment of light-emitting diode array. More particularly, FIGS. 10A and 10B illustrate the results of simulations in the case of an array having its first quotient a/λ in the range associated with area 704 enabling to determine optimal characteristics for the array and FIGS. 10C to 10E show results of simulations for the selected characteristics.

A 630-nm wavelength is here selected as previously and a curve 708 of FIG. 8 having its extremum corresponding to the greatest emitted intensity among the provided curves is selected. Quotient a/λ corresponding to the extremum is substantially equal to 0.85 and quotient 2πR/λ of the curve is substantially equal to 1.49. Thus, the determined pitch a is equal to 536.7 nm and the determined radius R is equal to 150 nm.

FIG. 10A illustrates the intensity emitted by the upper surfaces of the light-emitting diodes (Top Power) according to the total height h of the light-emitting diodes in the previously-determined conditions.

It is possible to observe two intensity peaks for heights h substantially equal to 180 nm and 325 nm.

A value of h is selected among these values. h is here selected to be equal to 325 nm, which corresponds to the strongest intensity.

FIG. 10B illustrates the intensity of the radiation emitted by the array of light-emitting diodes having the previously-determined characteristics according to thickness P1 of regions 102.

It is possible to observe, over the given range of values, a single maximum which enables to determine the value, here 40 nm, for thickness P1 of regions 102.

FIG. 10C illustrates the intensity of the radiation emitted by the upper surface of the array according to wavelength λ of the radiations emitted by the light-emitting diodes. Curve 902 corresponds to an array of light-emitting diodes which do not form a photonic crystal and curve 904 corresponds to an array forming a photonic crystal and having the previously-determined characteristics. The values have been normalized so that the maximum of curve 902 corresponds to value 1.

It can be observed that the array of light-emitting diodes according to an embodiment and having the previously-determined characteristics emits a radiation having an intensity, at the level of its upper surface, which is 1.6 times greater than for an array which does not form a photonic crystal.

FIG. 10D illustrates the intensity of the radiation emitted by the previously-described array according to the angle between the emitted radiation and the direction orthogonal to the upper surface of the array. It can be observed that the radiation is more directional than in the case described in relation with FIGS. 9A to 9E.

FIG. 10E illustrates the intensity of the radiation emitted by an array in cumulated fashion according to the solid angle measured with respect to the upper surface of the array. FIG. 10E comprises a curve 906 corresponding to an array comprising axial light-emitting diodes which do not form resonant cavities and a curve 908 corresponding to a photonic crystal comprising axial light-emitting diodes forming resonant cavities and having the previously-determined characteristics.

It can be observed that the array according to an embodiment (curve 908) supplies a more directional intensity. Indeed, the array corresponding to curve 908 supplies 50% of its intensity at a 33° solid angle while the array corresponding to curve 906 supplies 50% of its intensity at a 45° solid angle.

Thus, an array according the embodiment of FIG. 2 and having the previously-determined characteristics supplies a radiation of greater intensity and more directional than the radiation supplied by an array of light-emitting diodes corresponding to curve 906.

The inventors have performed similar simulations for arrays of light-emitting diodes such as described in relation with FIGS. 1 and 2 having different characteristics, particularly for light-emitting diodes having a cross-section of different shape, for light-emitting diodes having their active areas comprising multiple quantum wells rather than a single quantum well, for light-emitting diodes having a hexagonal rather than square mesh layout, or for different materials. The simulation results then enable to determine the values of the characteristics of the light-emitting diodes and of the array, as previously described, and show an increase in the intensity and the directivity of the radiation emitted by the array of light-emitting diodes.

Specific embodiments have been described. Various alterations and modifications will occur to those skilled in the art. In particular, although only the case of light-emitting diodes is described herein, the embodiments may also apply to photodiodes.

Various embodiments with different variations have been described hereabove. It should be noted that those skilled in the art may combine various elements of these various embodiments and variations without showing any inventive step.

1. An optoelectronic device comprising an array of axial diodes, each diode forming a resonant cavity having a standing electromagnetic wave forming therein, each light-emitting diode comprising an active area located substantially at the level of an extremum of the electromagnetic wave, the array forming a photonic crystal configured to maximize the intensity of the electromagnetic radiation supplied by the diode array.

2. The device of claim 1, wherein the array comprises a support having the diodes resting thereon, each diode comprising a stack of a first semiconductor region resting on the support, of the active area in contact with the first semiconductor region, and of a second semiconductor region in contact with the active area.

3. The device of claim 2, comprising a reflective layer between the support and the first regions of the diodes.

4. The device of claim 3, wherein the reflective layer is made of metal.

5. The device of claim 3, wherein the second regions of the diodes are covered with a conductive layer at least partly transparent to the radiations emitted by the diodes.

6. The device of claim 3, wherein the height (h) of at least one of the diodes is substantially proportional to kλ/2n, where λ is the wavelength of the radiation emitted by the diode, k is a positive integer, and n is substantially equal to the effective refraction index of the diode in the considered optical mode.

7. The device of claim 1, wherein the diodes are separated by an electrically-insulating material.

8. The device of claim 1, the array comprising at least first and second diode assemblies, the diodes of the first assembly having a same first height, the diodes of the second assembly having a same second height, the first and second heights being different.

9. The device of claim 2, wherein, for at least one of the diodes, the first region of the diode comprises at least two portions separated by an etch stop layer.

10. The device of claim 9, wherein each etch stop layer has a thickness in the range from 1 to 200 nm.

11. The device of claim 1, wherein the quotient of the pitch of the array to the wavelength of the supplied electromagnetic radiation is in the range from approximately 0.4 to approximately 0.92.

12. The device of claim 1, wherein the diodes are light-emitting diodes or photodiodes.

13. A method of manufacturing an optoelectronic device comprising an array of axial diodes, each diode forming a resonant cavity having a standing electromagnetic wave forming therein, the active area of each diode being located substantially at the level of an extremum of the electromagnetic wave, the array forming a photonic crystal configured to maximize the intensity of the electromagnetic radiation supplied by the diode array.

14. The method of claim 13, wherein the forming of the diodes of the array comprises:
forming first semiconductor regions on a substrate, the first regions being separated from one another by the pitch of the array;
forming an active area on each first region; and
forming a second semiconductor region on each active area.

15. The method of claim 14, comprising a first step of etching all the second regions so that they have a same height.

16. The method of claim 14, comprising a second step of etching all the first regions so that they have the height enabling the active area to be located at the level of an extremum of the electromagnetic wave.

17. The method of claim 16, wherein the second etch step is carried out before the forming of the active areas.

18. The method of claim 16, wherein the second etch step is preceded by a step of removing the substrate, the second etch step being carried out from the end of the diode which was closest to the substrate.

19. The method of claim 14, comprising forming at least one layer in the first region of at least one of the diodes capable of being used as a stop layer of the second etch step.

20. The method of claim 13, wherein the diodes are light-emitting diodes or photodiodes.
